(19) United States
(12) Patent Application Publication
(10) Pub. No.: US 2025/0212335 A1
(43) Pub. Date: Jun. 26, 2025

(54) PRINTED CIRCUIT BOARD

(71) Applicant: SAMSUNG ELECTRO-MECHANICS CO., LTD., Suwon-si, (KR)

(72) Inventors: Tae Kyung LEE, Suwon-si, (KR); Jin Uk LEE, Suwon-si, (KR); Yong Suk KIM, Suwon-si, (KR); Kwang Su KIM, Suwon-si, (KR); Joung Hun KIM, Suwon-si, (KR)

(73) Assignee: SAMSUNG ELECTRO-MECHANICS CO., LTD., Suwon-si, (KR)

(21) Appl. No.: 18/966,967

(22) Filed: Dec. 3, 2024

(30) Foreign Application Priority Data
Dec. 26, 2023 (KR) 10-2023-0190850

(51) Int. Cl. H05K 1/18; H05K 1/02; H05K 1/11

(52) U.S. Cl. CPC H05K 1/185; H05K 1/0298; H05K 1/115; H05K 2201/096; H05K 2201/10015; H05K 2201/10636

(57) ABSTRACT

A printed circuit board includes a substrate portion including a first insulating layer, s first wiring layers disposed on or within the first insulating layer, and a first via layer penetrating through at least a portion of the first insulating layer to connect the first wiring layers to each other, and a connection structure disposed within the substrate portion and including a capacitor portion, a passivation layer covering the capacitor portion, and a wiring portion disposed on the passivation layer.

### CROSS-REFERENCE TO RELATED APPLICATION(S)

This application claims benefit of priority to Korean Patent Application No. 10-2023-0190850 filed on Dec. 26, 2023 in the Korean Intellectual Property Office, the disclosure of which is incorporated herein by reference in its entirety.

### TECHNICAL FIELD

The present disclosure relates to a printed circuit board.

Recently, with the development of artificial intelligence (AI) technologies and the like, multi-chip packages that include memory chips such as High Bandwidth Memory (HBM) for exponentially increased data processing and processor chips such as a Central Processing Unit (CPU), a Graphics Processing Unit (GPU), an Application Specific Integrated Circuit (ASIC), and a Field Programmable Gate Array (FPGA) have been used. In detail, as the number of CPU and GPU cores in server products has increased rapidly, die split technology that may effectively increase the number of cores is becoming widespread, and die-to-die interconnection is required. Research is ongoing to design a substrate to include a connection structure that performs die-to-die interconnection to obtain a simplified substrate and package structure, improve the reliability of the connection structure, and increase yield.

### SUMMARY

An aspect of the present disclosure is to provide a printed circuit board in which die-to-die interconnection may be performed on a printed circuit board for mounting electronic components, semiconductor chips, and the like.

An aspect of the present disclosure is to provide a printed circuit board including a connection structure capable of implementing the function of a component in addition to the die-to-die interconnection.

An aspect of the present disclosure is to provide a printed circuit board having improving reliability.

According to an aspect of the present disclosure, a printed circuit board includes a substrate portion including a first insulating layer, first wiring layers disposed on or within the first insulating layer, and a first via layer penetrating through at least a portion of the first insulating layer to connect the first wiring layers to each other, and a connection structure disposed within the substrate portion and including a capacitor portion, a passivation layer covering the capacitor portion, and a wiring portion disposed on the passivation layer. The capacitor portion of the connection structure includes a plurality of dielectric layers, a first metal layer and a second metal layer alternately disposed with the plurality of dielectric layers interposed therebetween, a first insulating material disposed on the same level as the first metal layer, on one side of the capacitor portion, a second insulating material disposed on the same level as the second metal layer, on the other side opposite to the one side of the capacitor portion, a first connecting metal connected to the first metal layer, and a second connecting metal connected to the second metal layer.

According to an aspect of the present disclosure, a printed circuit board includes a substrate portion including a first insulating layer, and a first wiring layer disposed on or within the first insulating layer, and a connection structure disposed within the substrate portion and including a capacitor portion, a passivation layer covering the capacitor portion, and a wiring portion disposed on the passivation layer. The capacitor portion includes a plurality of dielectric layers, a first metal layer and a second metal layer alternately disposed with the plurality of dielectric layers interposed therebetween, a first connecting metal connected to the first metal layer, and a second connecting metal connected to the second metal layer. The first metal layer includes a metal different from a metal of the second metal layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIGS. 3A and 3B are cross-sectional views schematically illustrating a printed circuit board according to an example;

FIGS. 3C and 3D are cross-sectional views schematically illustrating a connection structure of a printed circuit board according to an example;

FIGS. 4A and 4B are cross-sectional views schematically illustrating a printed circuit board according to another example;

FIG. 4C is a cross-sectional view schematically illustrating a connection structure of a printed circuit board according to another example;

FIGS. 5A and 5B are cross-sectional views schematically illustrating a printed circuit board according to another example;

FIG. 5C is a cross-sectional view schematically illustrating a connection structure of a printed circuit board according to another example;

FIGS. 6A to 6J are cross-sectional views schematically illustrating a method of manufacturing a connection structure in methods of manufacturing a printed circuit board according to an example;

FIGS. 7A to 7J are cross-sectional views schematically illustrating a method of manufacturing a connection structure in methods of manufacturing a printed circuit board according to another example; and

FIGS. 8A to 8K are cross-sectional views schematically illustrating a method of manufacturing a connection structure in methods of manufacturing a printed circuit board according to another example.

### DETAILED DESCRIPTION

Hereinafter, the present disclosure will be described with reference to the attached drawings. In the drawings, the shapes and sizes of elements may be exaggerated or reduced for clearer description.

### Electronic Device

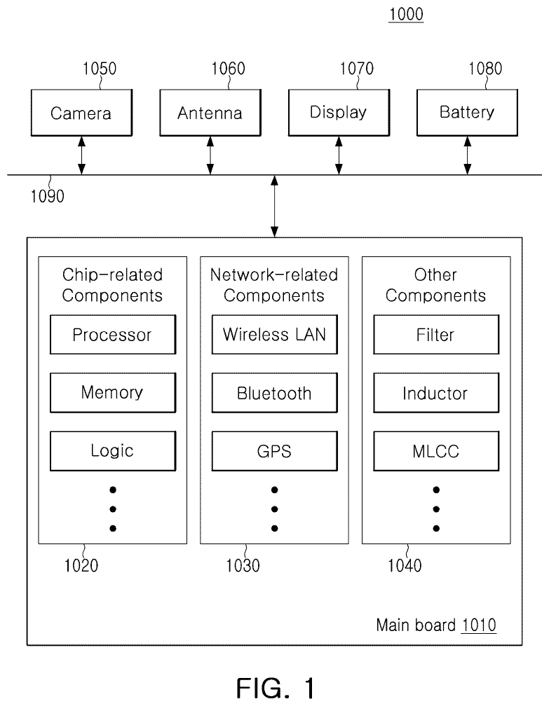

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other. The chip-related component 1020 may be in the form of a package including the above-described chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+(HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. For example, other electronic components may also include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, these other components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device used for processing data.

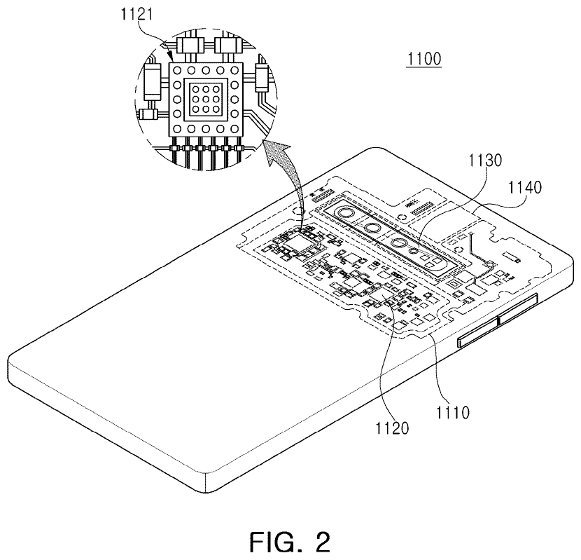

FIG. 2 is a schematic perspective view illustrating an example of an electronic device.

Referring to FIG. 2, the electronic device may be, for example, a smartphone 1100. A motherboard 1110 is accommodated inside the smartphone 1100, and various components 1120 are physically and/or electrically connected to the motherboard 1110. In addition, other components, such as a camera module 1130 and/or a speaker 1140, which may or may not be physically and/or electrically connected to the motherboard 1110, are accommodated therein. Some of the components 1120 may be the chip-related components described above, and may be, for example, a component package 1121, but are not limited thereto. The component package 1121 may be a printed circuit board in which electronic components including active components and/or passive components are surface-mounted. Alternatively, the component package 1121 may be a printed circuit board in which active components and/or passive components are built into the board. Meanwhile, the electronic device is not necessarily limited to a smartphone 1100, and may of course be another electronic device as described above.

### Printed Circuit Board

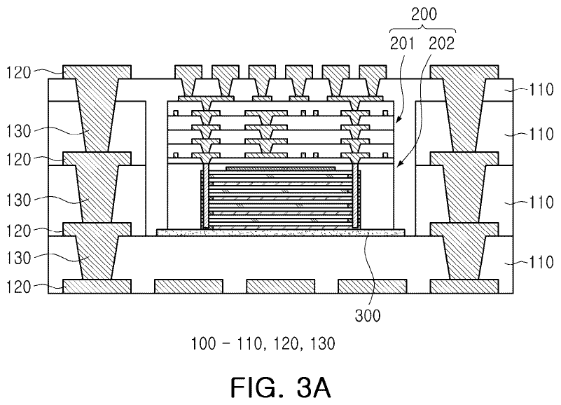

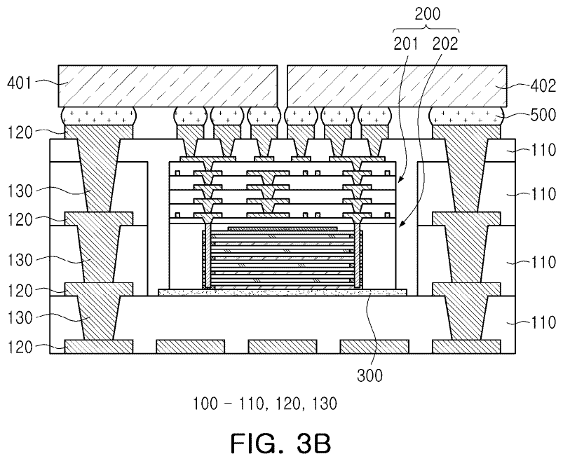

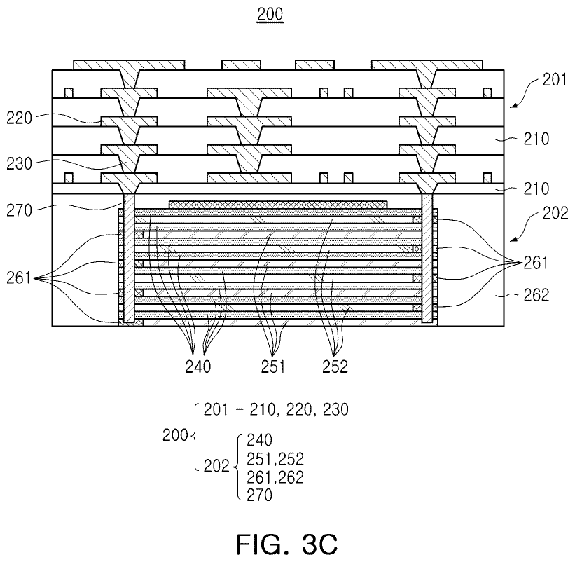

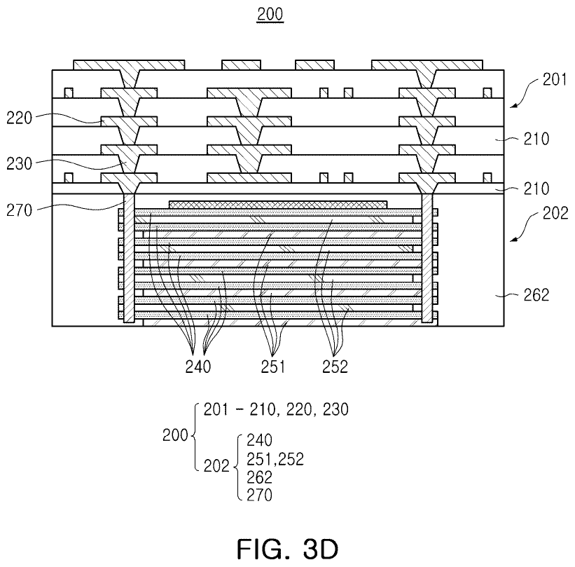

FIGS. 3A and 3B are cross-sectional views schematically illustrating a printed circuit board according to an example.

FIGS. 3C and 3D are cross-sectional views schematically illustrating a connection structure of a printed circuit board according to an example. The printed circuit board according to an example illustrated in FIGS. 3A and 3B may be more clearly understood by the connection structure of FIGS. 3C and 3D.

Referring to FIG. 3A, a printed circuit board according to an example includes a substrate portion 100 and a connection structure 200. The substrate portion 100 is a part that implements a signal path of the printed circuit board, and the connection structure 200 corresponds to a part that connects components such as chips to each other. The connection structure 200 is a part that implements a fine signal path corresponding to electronic components such as fine chips, and a plurality of electronic components such as chips may be placed with the connection structure 200 therebetween, and correspond to a part that performs mutual connection of electronic components such as chips and maintains an electrical signal path.

The substrate portion 100 may include a first insulating layer 110, a first wiring layer 120 placed on or within the first insulating layer 110, and a cavity penetrating through at least a portion of the first insulating layer 110. The substrate portion 100 may include a first via layer 130 penetrating through at least a portion of the first insulating layer 110 to connect the first wiring layers 120 to each other.

The first insulating layer 110 may be comprised of a plurality of insulating layers, and each of the first insulating layers 110 may include an insulating material. The insulating material may include a thermosetting resin such as an epoxy resin, a thermoplastic resin such as a polyimide, or a material including an inorganic filler, an organic filler, and/or glass fiber (Glass Fiber, Glass Cloth, and/or Glass Fabric) together with such a resin. The insulating material may be a photosensitive material and/or a non-photosensitive material. For example, the insulating material of the first insulating layer 110 may include, but is not limited to, an insulating material such as Prepreg (PPG), Resin Coated Copper (RCC), and the like, and may include Ajinomoto Build-up Film (ABF), Photo Imageable Dielectric (PID), FR-4, Bismaleimide Triazine (BT), or the like. However, the insulating material is not limited thereto, and if necessary, other polymer materials with excellent rigidity may be used.

The first wiring layer 120 may be comprised of a plurality of wiring layers, and each of the first wiring layers 120 may include a metal material. The metal material may include copper (Cu), aluminum (Al), silver (Ag), tin (Sn), gold (Au), nickel (Ni), lead (Pb), titanium (Ti), or alloys thereof. The first wiring layer 120 may include an electroless plating layer (or chemical copper) as a seed layer and an electrolytic plating layer (or electrolytic copper) as a plating layer, but is not limited thereto. A sputtering layer may be formed instead of chemical copper as the electroless plating layer. If necessary, a copper foil may be further included. The first wiring layer 120 may perform various functions according to the design of each layer, and for example, may include a ground pattern, a power pattern, a signal pattern, and the like. In this case, the signal pattern may include various signals, such as a data signal, excluding the ground pattern, the power pattern, and the like. These patterns may respectively include a line pattern, a plane pattern, and/or a pad pattern.

The first via layer 130 may be comprised of a plurality of via layers, and each first via layer 130 may include a micro via. The micro via may be a filled via that fills a via hole or a conformal via that is disposed along a wall surface of the via hole. The micro via may be disposed in a stacked type and/or a staggered type. Each first via layer 130 may include a metal material. The metal material may include a metal material such as copper (Cu), aluminum (Al), silver (Ag), tin (Sn), gold (Au), nickel (Ni), lead (Pb), titanium (Ti), or alloys thereof. Each of the connection via layers may include an electroless plating layer (or chemical copper) as a seed layer and an electrolytic plating layer (or electrolytic copper) as a plating layer, but is not limited thereto. Instead of the electroless plating layer, a sputtering layer may be formed. The first via layer 130 may perform various functions depending on the design of the layer, and for example, may include a ground via, a power via, a signal via, and the like. In this case, the signal via may include a via for transmitting various signals, such as a data signal, excluding the ground via, the power via, and the like.

Each first wiring layer 120 and each first via layer 130 may be formed integrally with each other, but is not limited thereto. The first wiring layer 120 and/or the first via layer 130 may be formed by any one of the Semi Additive Process (SAP), Modified Semi Additive Process (MSAP), Tending (TT), or Subtractive methods, but are not limited thereto, and any method capable of forming a circuit on a printed circuit board may be used without limitation.

The fact that the first wiring layer 120 is disposed on or within the first insulating layer 110 may indicate that the first wiring layer 120 may be disposed on the first insulating layer 110 or may be disposed to be embedded within the first insulating layer 110, and may refer to having a so-called coreless type substrate structure in which the first wiring layer 120 is embedded within the first insulating layer 110. In detail, referring to FIG. 3A, the first wiring layer 120 disposed at the bottom may have a structure embedded in the first insulating layer 110.

Meanwhile, the number of layers of the first insulating layer 110, the first wiring layer 120, and the first via layer 130 may be changed according to the design. In detail, the first insulating layer 110 may further include a core insulating layer including a core, the first wiring layer 120 may include copper foil, and the first via layer 130 may also include a through-via penetrating the core insulating layer. In this manner, the first insulating layer 110, the first wiring layer 120, and the first via layer 130 of the printed circuit board according to an example may have a configuration that may be utilized by anyone with common knowledge in the field of printed circuit board technology.

The cavity may penetrate at least a portion of the first insulating layer 110. The cavity may correspond to a position where the connection structure 200 is mounted. That the cavity may penetrate at least a portion of the first insulating layer 110 may mean that it penetrates any continuous first insulating layer 110 among a plurality of first insulating layers 110, or may mean that it penetrates only a portion of any first insulating layer 110, and is not limited thereto, and may also mean that it penetrates any continuous first insulating layer 110 while penetrating a portion of another arbitrary first insulating layer 110. Although not illustrated in FIGS. 3A and 3B, if the cavity penetrates only a portion of the first insulating layer 110, the upper surface of the first insulating layer 110 may have a step.

A method for forming a cavity may be used without limitation if it is a method used in a known cavity forming process. For example, a mechanical drilling process such as laser processing or a blasting process may be used, but is not limited thereto. At this time, a portion of the first wiring layer 120 disposed on the first insulating layer 110 may perform the function of a stopper layer, and a separate stopper layer may be disposed on the upper surface of the first insulating layer 110 in advance and then removed by etching or the like after cavity processing. When a stopper layer is formed, the stopper layer may be formed simultaneously with the first wiring layer 120. The wall surface of the cavity penetrating through at least a portion of the first insulating layer 110 may be configured as a side surface of the first insulating layer 110, and the bottom surface of the cavity may be configured as an upper surface of the first insulating layer 110. Meanwhile, although not illustrated in FIGS. 3A and 3B, the bottom surface of the cavity may be configured as a stopper layer disposed on the same level as the first wiring layer 120.

A printed circuit board according to an example includes a connection structure 200. The connection structure 200 may be disposed within the cavity, and the connection structure 200 may include a wiring portion 201 and a capacitor portion 202. The detailed configuration of the wiring portion 201 and the capacitor portion 202 of the connection structure 200 may be more clearly explained through FIG. 3C and FIG. 3D, and thus a detailed description will be given later.

The wiring portion 201 of the connection structure 200 may include a second insulating layer 210, a second wiring layer 220 disposed on or within the second insulating layer 210, and a second via layer 230 penetrating through at least a portion of the second insulating layer 210 to connect the second wiring layers 220 to each other.

The capacitor portion 202 of the connection structure 200 may include a plurality of dielectric layers 240, a first metal layer 251 and a second metal layer 252 alternately disposed with the plurality of dielectric layers 240 interposed therebetween, an insulating material 261 disposed on the same level as the first metal layer 251 on one side of the capacitor portion 202, or disposed on the same level as the second metal layer 252 on the other side opposite to one side of the capacitor portion 202, and a connecting metal 270 that penetrates through a portion of a plurality of dielectric layers 240, a portion of the first metal layer 251, and a portion of the insulating material 261 to connect the first metal layers 251 to each other, or that penetrates through a portion of a plurality of dielectric layers 240, a portion of the second metal layer 252, and a portion of the insulating material 261 to connect the second metal layers 252 to each other. Meanwhile, the connection structure may further include a passivation layer 262 that covers the capacitor portion 202.

The wiring portion 201 of the connection structure 200 may have a higher wiring density than the substrate portion 100. A higher wiring density is a relative concept, and for example, may mean that the average pitch of the wiring included in the second wiring layer 220 may be smaller than the average pitch of the wiring included in the first wiring layer 120. The pitch may be measured by capturing an image of a cut section of a printed circuit board with a scanning microscope, and the average pitch may be an average value of the pitches between the wirings measured at five arbitrary points. In addition, the average interlayer insulation distance between the second wiring layers 220 may be smaller than the average interlayer insulation distance between the plurality of first wiring layers 120. The interlayer insulation distance may also be measured by capturing an image of a cut section of a printed circuit board with a scanning microscope, and the average interlayer insulation distance may be an average value of the insulation distances between adjacent wiring layers measured at five arbitrary points. For example, the wiring included in the second wiring layer 220 may be a high-density circuit having a smaller L/S (Line/Space) than the wiring included in the first wiring layer 120. As a non-limiting example, the wiring included in the second wiring layer 220 may have a line/space of approximately 2/2 μm, but is not limited thereto. Since the wiring portion 201 of the connection structure 200 has a higher density than the wiring of the substrate portion 100, it may be effective when interconnecting electronic components such as semiconductor chips. For example, it may be effective for die-to-die interconnection.

In this sense, the thickness of the second insulating layer 210 may be thinner than the thickness of the first insulating layer 110, and the thickness of the second wiring layer 220 may be thinner than the thickness of the first wiring layer 120. The thickness of the insulating layer is a concept that includes an approximate value, and may mean the vertical distance across the upper and lower surfaces of the insulating layer. The thickness of the second insulating layer 210 being thinner than the thickness of the first insulating layer 110 may mean that the thickness of one of the second insulating layers 210 among the plurality of second insulating layers 210 is thinner than the thickness of one of the first insulating layers 110 among the plurality of first insulating layers 110, but the present disclosure is not limited thereto. The thicknesses of the first insulating layer 110 and the second insulating layer 210 may be respectively measured by capturing an image of the cross-section of the printed circuit board with a scanning microscope, and may be the average value of the thicknesses of the insulating layers measured at five arbitrary points. The thickness of the wiring layer may be interpreted in the same sense as the thickness of the insulating layer.

Details regarding other configurations of the connection structure will be described later.

A printed circuit board according to an example may further include an adhesive layer 300.

The connection structure 200 is placed in the cavity of the substrate portion 100, and the connection structure 200 may be attached to the bottom surface of the cavity via the adhesive layer 300. The adhesive layer 300 may be placed to cover the lower surface of the connection structure 200. As the adhesive layer 300, a typical adhesive film such as a die attach film (DAF) may be used, but is not limited thereto, and any means capable of attaching other components such as electronic components or connection structures to a printed circuit board, such as a known tape, may be used without limitation.

Referring to FIG. 3B, a printed circuit board according to an example may include a first semiconductor chip 401 disposed on a portion of the substrate portion 100 and a portion of the connection structure 200, and a second semiconductor chip 402 disposed on a portion of the substrate portion 100 and a portion of the connection structure 200, and may include a connection member 500 that respectively connects the first semiconductor chip 401 and the second semiconductor chip 402 to the substrate portion 100 and the connection structure 200. The first semiconductor chip 401 may be disposed to be electrically connected to a portion of the substrate portion 100 and a portion of the connection structure 200, and the second semiconductor chip 402 may be electrically connected to a portion of the substrate portion 100 and a portion of the connection structure 200 and may be electrically connected to the first semiconductor chip 401 through the connection structure 200.

The first semiconductor chip 401 and the second semiconductor chip 402 may each include an integrated circuit (IC) die in which hundreds to millions of elements are integrated into a single chip. In this case, the integrated circuit may be, for example, a logic chip such as a central processor (for example, a CPU), a graphic processor (for example, a GPU), a field programmable gate array (FPGA), a digital signal processor, an encryption processor, a microprocessor, a microcontroller, an application processor (for example, an AP), an analog-to-digital converter, an Application-Specific IC (ASIC), and the like, but is not limited thereto, and may of course be a memory chip such as a volatile memory (for example, DRAM), a non-volatile memory (for example, ROM), a flash memory, a High Bandwidth Memory (HBM), etc., or a Power Management IC (PMIC). For example, the first semiconductor chip 401 may include a logic chip such as a GPU, and the second semiconductor chip 402 may include a memory chip such as an HBM. Alternatively, the first semiconductor chip 401 and the second semiconductor chip 402 may be divided by a die split and may be divided logic chips having different cores.

The first semiconductor chip 401 and the second semiconductor chip 402 may each be formed based on an active wafer, and in this case, silicon (Si), germanium (Ge), gallium arsenide (GaAs), or the like may be used as the base material forming each body. Various circuits may be formed in the body. A connection pad may be formed in each body, and the connection pad may include a conductive material such as aluminum (Al), copper (Cu), or the like. The first semiconductor chip 401 and the second semiconductor chip 402 may be a bare die, and in this case, a metal bump may be disposed on the connection pad. Alternatively, the first semiconductor chip 401 and the second semiconductor chip 402 may be packaged dies, and in this case, an additional redistribution layer may be formed on the connection pad, and a metal bump may be disposed on the redistribution layer.

The first semiconductor chip 401 and the second semiconductor chip 402 may be connected to the substrate portion 100 and the connection structure of the printed circuit board through the connection member 500. The connection member 500 may be formed of a low-melting point metal, for example, solder such as tin (Sn)-aluminum (Al)-copper (Cu), but is not limited thereto. The connection member 500 may be formed as a multilayer or a single layer. When formed as a multilayer, the connection member 500 may include copper pillars and solder, and when formed as a single layer, the connection member 500 may include tin-silver solder or copper, but is not limited thereto. In addition, any means that may serve as a mediator to electrically connect semiconductor chips or electronic components to the substrate portion 100 and/or the connection structure 200 may be used without limitation. In FIG. 3B, two semiconductor chips are mounted, but the present disclosure is not limited thereto, and a larger number of semiconductor chips may be mounted, and a larger number of semiconductor chips may be electrically connected by the connection structure 200.

Referring to FIG. 3C, the connection structure 200 of the printed circuit board according to an example may include a wiring portion 201 and a capacitor portion 202.

The wiring portion 201 of the connection structure 200 may include a second insulating layer 210, a second wiring layer 220 disposed on or within the second insulating layer 210, and a second via layer 230 penetrating through at least a portion of the second insulating layer 210 to connect the second wiring layers 220 to each other.

The second insulating layer 210 may be comprised of a plurality of insulating layers, and each of the second insulating layers 210 may include an insulating material. The insulating material may include a thermosetting resin such as an epoxy resin, a thermoplastic resin such as a polyimide, or a material including an inorganic filler, an organic filler, and/or glass fiber (Glass Fiber, Glass Cloth, and/or Glass Fabric) together with such a resin. The insulating material may be a photosensitive material and/or a non-photosensitive material. For example, the insulating material of the second insulating layer 210 may be, but is not limited to, an insulating material such as Prepreg (PPG), Resin Coated Copper (RCC), and the like, and may also be, but is not limited to, Ajinomoto Build-up Film (ABF), Photo Imageable Dielectric (PID), FR-4, Bismaleimide Triazine (BT), or the like. However, the present disclosure is not limited thereto, and other polymer materials with excellent rigidity may be used as needed. Meanwhile, the second insulating layer 210 may include an insulating material comprised of an organic material. For example, the connection structure 200 may be an organic bridge. Accordingly, even if the connection structure 200 is disposed on the upper portion of the substrate portion 100, unlike the case where the connection structure 200 is a silicon bridge, reliability problems due to coefficient of thermal expansion (CTE) mismatch may hardly occur. In addition, for example, when the connection structure 200 includes an organic insulating material, the process difficulty and cost for formation may be reduced. For the formation of a microcircuit, a Photo Imageable Dielectric (PID) may be used as the organic insulating material, but the present disclosure is not limited thereto.

The second wiring layer 220 may be comprised of a plurality of wiring layers, and each of the second wiring layers 220 may include a metal material. As the metal material, copper (Cu), aluminum (Al), silver (Ag), tin (Sn), gold (Au), nickel (Ni), lead (Pb), titanium (Ti), or alloys thereof may be used. Each of the second wiring layers 220 may include an electroless plating layer (or chemical copper) as a seed layer and an electrolytic plating layer (or electrolytic copper) as a plating layer, but is not limited thereto. Instead of chemical copper, a sputtering layer may be formed as the electroless plating layer. If necessary, a copper foil may be further included. The second wiring layers 220 may respectively perform various functions according to the design of the corresponding layer, and for example, may include a ground pattern, a power pattern, a signal pattern, and the like. In this case, the signal pattern may include various signals, such as a data signal, excluding the ground pattern, the power pattern, and the like. These patterns may respectively include a line pattern, a plane pattern, and/or a pad pattern. The second wiring layer 220 disposed on the uppermost side among the second wiring layers 220 may have a structure exposed from the second insulating layer 210, and may further include a surface treatment layer on the exposed surface.

The second via layer 230 may be comprised of a plurality of via layers, and each of the second via layers 230 may include a micro via. The micro via may be a filled via that fills a via hole or a conformal via that is disposed along the wall surface of the via hole. The micro via may be disposed in a stacked type and/or a staggered type. Each of the second via layers 230 may include a metal material. The metal material may include a metal material such as copper (Cu), aluminum (Al), silver (Ag), tin (Sn), gold (Au), nickel (Ni), lead (Pb), titanium (Ti), or alloys thereof. The second via layer 230 may include an electroless plating layer (or chemical copper) as a seed layer and an electrolytic plating layer (or electrolytic copper) as a plating layer, but is not limited thereto. A sputtering layer may be formed instead of a chemical copper as the electroless plating layer. The second via layer 230 may perform various functions depending on the design of the corresponding layer, and for example, may include a ground via, a power via, a signal via, and the like. In this case, the signal via may include a via for transmitting various signals, such as a data signal, excluding the ground via, the power via, and the like.

Each second wiring layer 220 and each second via layer 230 may be formed integrally with each other, but are not limited thereto. The second wiring layer 220 and/or the second via layer 230 may be formed by any one of the Semi Additive Process (SAP), Modified Semi Additive Process (MSAP), Tenting (TT), or Subtractive methods, but are not limited thereto, and any method capable of forming a circuit in a printed circuit board or a connection structure may be used without limitation.

The capacitor portion 202 of the connection structure 200 may include a plurality of dielectric layers 240, first metal layers 251 and second metal layers 252 alternately disposed with the plurality of dielectric layers 240 therebetween, an insulating material 261 disposed on the same level as the first metal layer 251 on one side of the capacitor portion 202 or disposed on the same level as the second metal layer 252 on the other side opposite to one side of the capacitor portion 202, and a connecting metal 270 that penetrates a portion of the plurality of dielectric layers 240, a portion of the first metal layer 251, and a portion of the insulating material 261 to connect the first metal layers 251 to each other, or that penetrates a portion of the plurality of dielectric layers 240, a portion of the second metal layer 252, and a portion of the insulating material 261 to connect the second metal layers 252 to each other. Meanwhile, the connection structure may further include a passivation layer 262 that covers the capacitor portion 202.

The dielectric layer 240 may be comprised of a plurality of dielectric layers 240, and the dielectric layer 240 may include a dielectric material. The dielectric material may include an oxide or a nitride, and may include one or more materials from among SiO₂, Si₃N₄, Al₂O₃, AlN, MgO, Y₂O₃, HfO₂, ZrO₂, and Ta₂O₃. The dielectric layer 240 including an oxide or a nitride may have various values of permittivity from 1 to 80. In addition, the dielectric layer 240 may be preferably selected from a material having a band gap energy (Eg) of 4 eV or more in consideration of the function and characteristics of the material, and may include at least one material among the materials described above, but is not necessarily limited thereto, and any material including an oxide or a nitride may be used without limitation. Even if a dielectric material with a high permittivity is selected, if the band gap energy is low, the dielectric characteristics of the dielectric layer 240 may not be implemented, and therefore, at least one material among the materials described above may be included. The plurality of dielectric layers 240 may include substantially the same dielectric material, but is not necessarily limited thereto, and the plurality of dielectric layers 240 may be disposed to include various materials as needed. Meanwhile, the dielectric material of the dielectric layer 240 is not limited thereto, and may be used without limitation as long as it is disposed between the first metal layer 251 and the second metal layer 252, performing the function of the internal electrode, and may perform the function as a dielectric.

The dielectric layer 240 may be formed by performing a deposition process, and in detail, may be formed through thin film deposition. The thin film deposition process may be selected from physical vapor deposition (PVD), chemical vapor deposition (CVD), atomic layer deposition (ALD), molecular vapor deposition (MVD), or the like. The dielectric layer 240 may be deposited on a support substrate wafer, and the deposition process may be performed in layers to implement a flat surface. However, the present disclosure is not necessarily limited thereto, and the dielectric layer may be formed by a method of laminating sheets through screening, or the like, and there is no limitation on the method of forming the dielectric layer 240, and there may be no limitation if it is a known method of laminating the dielectric layer 240.

The first metal layer 251 and the second metal layer 252 may each include a metal material as a material having excellent electrical conductivity. The metal material may include at least one of titanium (Ti), molybdenum (Mo), tungsten (W), iron (Fe), cobalt (Co), nickel (Ni), palladium (Pd), platinum (Pt), copper (Cu), silver (Ag), gold (Au), zinc (Zn), aluminum (Al), tin (Sn), lead (Pb), calcium (Ca), and alloys thereof. The first metal layer 251 and the second metal layer 252 may include metal materials that are substantially different from each other. Since the first metal layer 251 and the second metal layer 252 may include metal materials that are different from each other, in the operation of removing a portion of the first metal layer 251 in the method of manufacturing a printed circuit board, the second metal layer 252 may not react, and in the operation of removing a portion of the second metal layer 252, the first metal layer 251 may not react. For example, since the first metal layer 251 and the second metal layer 252 include different metal materials, in the operation of forming the connecting metal 270 for connecting the first metal layers 251 to each other and the connecting metal 270 for connecting the second metal layers 252 to each other, the first metal layer 251 and the second metal layer 252 may be independently connected. As a non-limiting example, the first metal layer 251 may include molybdenum (Mo), and the second metal layer 252 may include titanium (Ti).

Meanwhile, it is not necessarily limited thereto, and if there is a method of forming the first metal layer 251 and the second metal layer 252 in a manner that the first metal layer 251 and the second metal layer 252 may be independently connected to each other using other means or processes, the first metal layer 251 and the second metal layer 252 may include substantially the same metal.

The first metal layer 251 and the second metal layer 252 may each be formed by a deposition process, and may be formed by the same method as the deposition process for forming the dielectric layer 240, but the present disclosure is not necessarily limited thereto, and a different deposition process may be used. Meanwhile, it is not necessarily limited thereto, and the first metal layer 251 and the second metal layer 252 may be formed by printing a conductive paste on a ceramic green sheet, or may be formed through plating, and the method of forming the metal layer is not limited.

The first metal layer 251 and the second metal layer 252 may be disposed alternately with the dielectric layer 240 interposed therebetween. The fact that the first metal layer 251 and the second metal layer 252 are disposed alternately with the dielectric layer 240 interposed therebetween may mean that the dielectric layer 240, the first metal layer 251, the dielectric layer 240, and the second metal layer 252 are disposed alternately. Meanwhile, the present disclosure is not necessarily limited thereto, and the first metal layer 251 may be disposed multiple times, the second metal layer 252 may be disposed multiple times, and the like, so that it is sufficient if the first metal layer 251 and the second metal layer 252 may each function as internal electrodes of the capacitor portion 202 by being disposed with a certain tendency. Meanwhile, referring to FIG. 3C, the first metal layer 251 is illustrated as being disposed at the lowest side of the capacitor portion 202, but it is not necessarily limited thereto, and the lowest side of the capacitor portion 202 may be a dielectric layer 240, and the second metal layer 252 may also be disposed.

The first metal layer 251 and the second metal layer 252 may each perform the function of internal electrodes of the capacitor portion 202. For example, the first metal layer 251 and the second metal layer 252 are charged with opposite polarities to each other and may have capacitance. The first metal layer 251 and the second metal layer 252 are disposed to correspond to each other to form a pair, and may be disposed to face each other with the dielectric layer 240 interposed therebetween. Through this structure, charges are charged in respective metal layers to perform the function of a capacitor.

The insulating material 261 may be disposed on the same level as the first metal layer 251 on one side of the capacitor portion 202 and positioned between the dielectric layers 240. The insulating material 261 may also be disposed on the same level as the second metal layer 252 on the other side opposite to the one side of the capacitor portion 202 and positioned between the dielectric layers 240. In a method of manufacturing a printed circuit board, when an operation of removing a portion of the second metal layer 252 on the other side is performed after an operation of removing a portion of the first metal layer 251 on one side, a groove is generated in which each metal layer has been removed. Since the insulating material 261 may be disposed to fill the groove, the insulating material 261 may be disposed on the same level as the first metal layer 251 on one side of the capacitor portion 202, and may be disposed on the same level as the second metal layer 252 on the other side of the capacitor portion 202, and the insulating material 261 may be positioned between the dielectric layers 240. At this time, since the insulating material 261 may be positioned in the grooves of the first metal layer 251 and the second metal layer 252, the thickness of the insulating material 261 may be substantially the same as the thickness of the first metal layer 251 and/or the second metal layer 252. In one or more aspects, the term “being substantially the same” (“about,” “approximately,” etc.) may indicate “being the same” or being within an industry-accepted tolerance, due to a process error or a measurement error recognizable by one of ordinary skill in the art provide, for the corresponding term and/or relativity between items, such as a tolerance of +1%, +5%, or +10% of the actual value stated, and other suitable tolerances.

The insulating material 261 may include an insulating material. The insulating material may include an organic insulating material or an inorganic insulating material. The organic insulating material may include an organic film, and as an insulating polymer, may include a thermosetting resin such as an epoxy resin, a thermoplastic resin such as a polyimide, and a material including an inorganic filler, an organic filler, and/or glass fiber (Glass Fiber, Glass Cloth, and/or Glass Fabric) together with such a resin. As a non-limiting example, the insulating material may include Ajinomoto Build-up Film (ABF). The inorganic insulating material may include a ceramic material and may include a glassy material. The glassy material may be, but is not limited to, silicon oxide including a metal element, and may include silicon-based oxide or nitride. Meanwhile, the material of the insulating material 261 is not limited thereto, and any insulating material that may fill the grooves respectively formed in the first metal layer 251 and the second metal layer 252 may be used without limitation, and for example, a material for passivation known in the art may be used.

The insulating material 261 may be formed to fill the grooves using a deposition process such as Atomic Layer Deposition (ALD), but may also be formed by performing a process such as coating. Meanwhile, the present disclosure is not limited thereto, and any process that may fill the groove with an insulating material may be used without limitation.

As the insulating material 261 is formed to fill the grooves formed in the first metal layer 251 and the second metal layer 252, the first metal layer 251 of the capacitor portion 202 may not be connected to the second metal layer 252, and the groove is not empty, so that the capacitor portion 202 may be protected during processing in the subsequent operation of forming the connecting metal 270. Meanwhile, the insulating material 261 may also be placed on the uppermost side of the dielectric layer 240. This may be a result of patterning the insulating material 261 in the operation of forming the insulating material 261, and the insulating material 261 may be disposed on the uppermost dielectric layer 240 to control the flatness of the connecting metal 270.

Meanwhile, the arrangement of the insulating material 261 is not limited to that illustrated in FIG. 3C, and may be extended to cover the side of a plurality of dielectric layers 240 while being formed to fill the grooves.

The connecting metal 270 may connect the first metal layers 251 to each other or the second metal layers 252 to each other. For example, the connecting metal 270 may connect the internal electrodes of the capacitor portion 202 to each other and perform the function of an external electrode connected externally.

The connecting metal 270 may penetrate the dielectric layer 240, the second metal layer 252, and the insulating material 261 on one side of the capacitor portion 202. The connecting metal 270 disposed on one side of the capacitor portion 202 penetrates the second metal layer 252 and does not penetrate the first metal layer 251, so that the second metal layers 252 may be connected to each other. The connecting metal 270 disposed on the other side of the capacitor portion 202 may penetrate the dielectric layer 240, the first metal layer 251, and the insulating material 261. The connecting metal 270 disposed on the other side penetrates the first metal layer 251 without penetrating the second metal layer 252, so that the first metal layers 251 may be connected to each other. Accordingly, one side of the capacitor portion 202 may have the connecting metal 270 connected to the second metal layer 252, and the other side facing one side of the capacitor portion 202 may have the connecting metal 270 connected to the first metal layer 251.

The connecting metal 270 may include a metal material. The metal material may include copper (Cu), aluminum (Al), silver (Ag), tin (Sn), gold (Au), nickel (Ni), lead (Pb), titanium (Ti), or alloys thereof, and preferably, may include copper (Cu). The connecting metal 270 may include a metal different from the metal material of each of the first metal layer 251 and the second metal layer 252. The connecting metal 270 may be formed by plating after processing a via hole penetrating the laminate of the capacitor portion 202, but the method of forming the connecting metal 270 is not limited thereto, and any method known in the art for performing interlayer connection may be used without limitation.

The connecting metal 270 may function as an external electrode for connecting the first metal layer 251 or the second metal layer 252 of the capacitor portion 202 to the second wiring layer 220, and the connecting metal 270 may be connected to the second wiring layer 220 through the second via layer 230.

The connection structure 200 may include a passivation layer 262. The passivation layer 262 may be formed to cover the laminate of the capacitor portion 202. The passivation layer 262 may include an insulating material, and may use a known passivation resin used in electronic components such as semiconductor chips. As a non-limiting example, the passivation layer 262 may include polyimide as an insulating resin. Meanwhile, without being limited thereto, the passivation layer 262 may include a thermosetting resin such as an epoxy resin, a thermoplastic resin such as polyimide, and a material including an inorganic filler, an organic filler, and/or glass fiber (glass fiber, glass cloth, and/or glass Fabric) together with such resins, as an insulating polymer. As a non-limiting example, the insulating material may include Ajinomoto Build-up Film (ABF).

Since the passivation layer 262 may cover the capacitor portion 202 to form a flat surface, the wiring portion 201 of the connection structure 200 may be placed on the flattened passivation layer 262.

Meanwhile, referring to FIG. 3D, the connection structure 200 of the printed circuit board according to an example may fill the grooves formed in the first metal layer 251 and the second metal layer 252 with the passivation layer 262, instead of the insulating material 261. In this case, the operation of forming the insulating material 261 may be omitted, and the groove may be filled in the operation of forming the passivation layer 262 after forming the groove in the first metal layer 251 and the second metal layer 252. For example, rather than a boundary being clearly observed between the insulating material 261 and the passivation layer 262, it may mean that the passivation layer 262 is formed integrally with the insulating material 261 to fill the groove. In this case, while reducing the process step by one step, the insulating structure may be maintained by filling the groove formed in the first metal layer 251 and the second metal layer 252, and the capacitor portion 202 may be protected in the operation of forming the connecting metal 270.

Meanwhile, in FIGS. 3A to 3D, one capacitor portion 202 is illustrated as being disposed in the connection structure 200, but the present disclosure is not limited thereto, and a plurality of capacitor portions 202 may be disposed in parallel in the horizontal direction and respectively may be connected to the wiring portion or may be connected to each other through the second wiring layer 220, or may be connected in series in the vertical direction.

Meanwhile, the printed circuit board according to the example is not limited to FIGS. 3A and 3B, and the connection structure is not limited to the configuration illustrated in FIGS. 3C and 3D, and the printed circuit board may further include a general configuration of the printed circuit board in addition thereto. For example, the printed circuit board may further include a configuration that may be utilized by a person having ordinary knowledge in the relevant technical field.

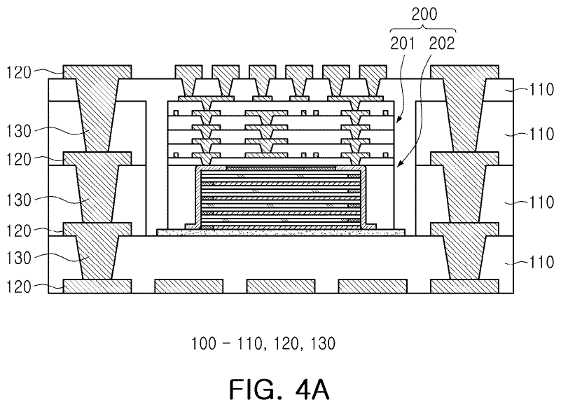

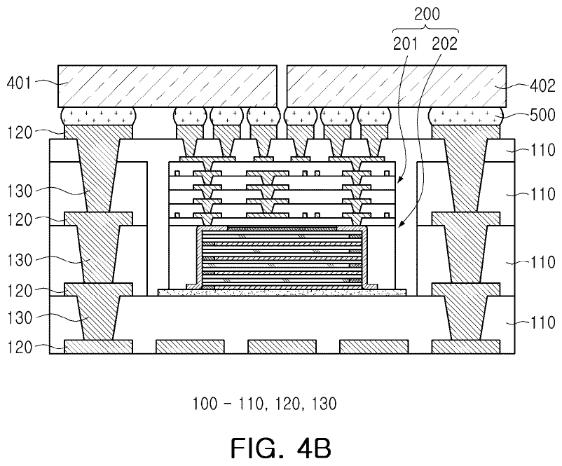

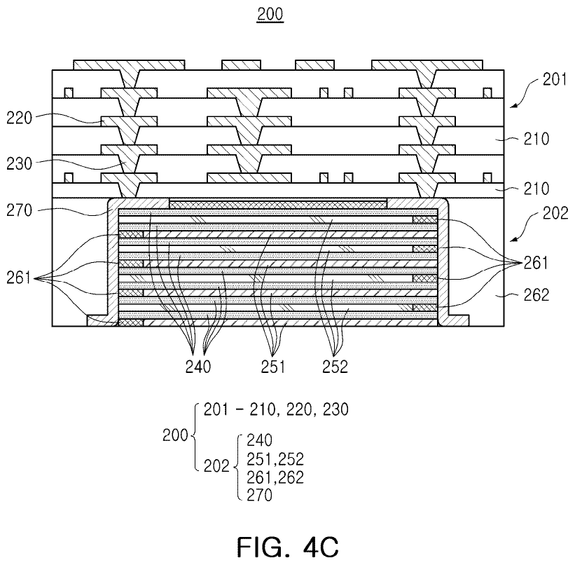

FIGS. 4A and 4B are cross-sectional views schematically illustrating a printed circuit board according to another example, and FIG. 4C is a cross-sectional view schematically illustrating a connection structure of a printed circuit board according to another example. The printed circuit board according to another example illustrated in FIGS. 4A and 4B may be more clearly understood by the connection structure of FIG. 4C.

In the connection structure 200 of the printed circuit board according to another example, the connecting metal 270 may be disposed on one side and the other side of the capacitor portion 202. For example, the connecting metal 270 may be disposed on one side and the other side of the capacitor portion 202 without penetrating the dielectric layer 240, the first metal layer 251, the second metal layer 252, and the insulating material 261.

The connecting metal 270 may be disposed on one side and the other side through plating after forming the laminate of the capacitor portion 202. At this time, the connecting metal 270 may include an electroless plating layer and an electrolytic plating layer, and may also include a sputtering layer if necessary. In addition, since the connecting metal 270 may include a Ti/Cu sputtering layer, and in this case, the second metal layer 252 and the connecting metal 270 may include the same metal material.

The connecting metal 270 may extend to a portion of the dielectric layer 240. For example, the connecting metal 270 may extend to a portion of the upper surface of the dielectric layer 240 disposed at the top. The second via layer 230 may be connected in the area where the connecting metal 270 is disposed on a portion of the upper surface. Since the connecting metal 270 does not penetrate the capacitor portion 202, a defect may not occur in the through hole formation operation.

Meanwhile, among the configurations other than the arrangement of the connecting metal 270, the configuration of the connection structure according to an example may also be applied to the connection structure according to another example, and thus a redundant description thereof will be omitted.

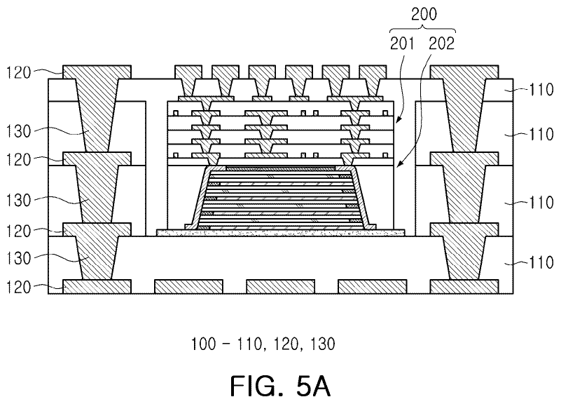

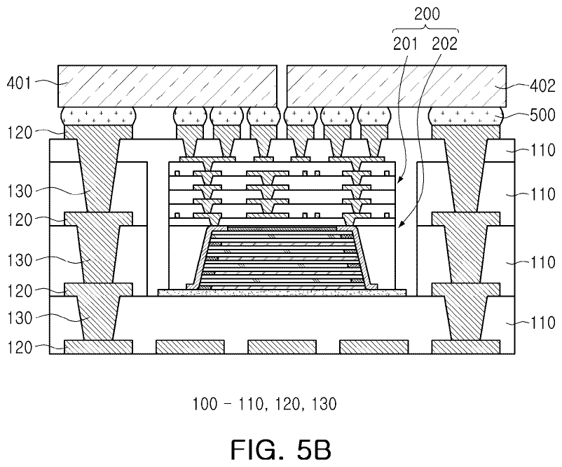

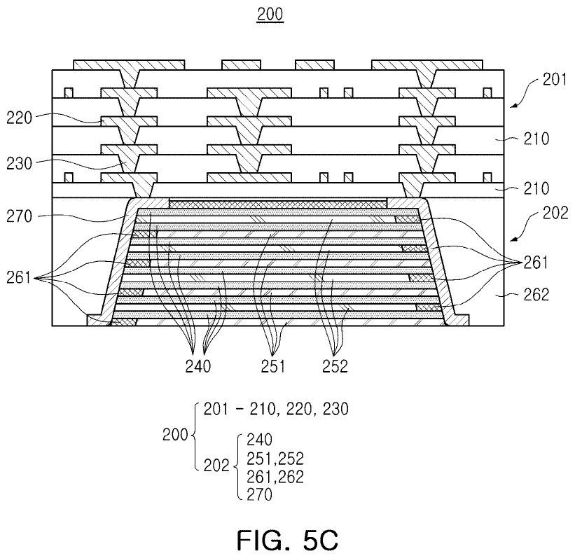

FIGS. 5A and 5B are cross-sectional views schematically illustrating a printed circuit board according to another example, and FIG. 5C is a cross-sectional view schematically illustrating a connection structure of a printed circuit board according to another example. The printed circuit board according to another example illustrated in FIGS. 5A and 5B may be more clearly understood by the connection structure of FIG. 5C.

In the connection structure 200 of the printed circuit board according to another example, the capacitor portion 202 may have an inclined surface. For example, the capacitor portion 202 may have a trapezoidal shape and may have a tapered shape so that the width of the upper side is narrower than the width of the lower side. This may be a result of forming a capacitor laminate, processing a portion of the laminate to have an inclined surface, and then connecting the electrodes. As the capacitor portion 202 may have an inclined surface, deposition may be easier in the operation of forming the insulating material 261, and the connecting metal 270 may be formed evenly. At this time, the inclined surface formed in the capacitor portion 202 may form an acute angle with the bottom surface of the capacitor portion 202. As a non-limiting example, it may be preferable that the inclined surface of the side surface of the capacitor portion 202 and the bottom surface of the capacitor portion 202 form an angle of 80 degrees or less. However, as long as the capacitor portion 202 is placed, the angle formed by the side surface of the capacitor portion 202 and the bottom surface of the capacitor portion 202 should of course be greater than 0 degree. The smaller the inclined angle of the side surface of the capacitor portion 202, the better the connectivity between the connecting metal 270 and the first metal layer 251 and the second metal layer 252.

As the side surface of the capacitor portion 202 has an inclined surface, the connecting metal 270 may also have an inclined surface, and the connecting metal 270 and the bottom surface of the capacitor portion 202 may have an acute angle, and may have an inclined angle substantially the same as the inclined angle of the side surface of the capacitor portion 202. At this time, the inclined angle formed by the inclined surface of the capacitor portion 202 may be measured by capturing an image of a cross-section in the stacking direction of the connection structure 200 or the capacitor portion 202 using a scanning microscope, and may be measured using the angle formed by the extension line of the actual inclined surface of the capacitor portion 202 and the bottom surface of the capacitor portion 202 measured in any five areas, and may be measured using the angle formed by the extension line of the inclined surface of the connecting metal 270 and the bottom surface of the capacitor portion 202. Meanwhile, if it is a known method of measuring the inclination angle formed by the actual surface and surface meeting, rather than the uneven slope measured at only one point, the method may be used without limitation.

Meanwhile, among the configurations other than the shape of the capacitor portion 202, the configuration of the connection structure according to an example and the configuration of the connection structure according to another example may also be applied to the connection structure according to another example, and thus a redundant description thereof is omitted.

### Method of Manufacturing Printed Circuit Board

A printed circuit board according to an example may include an operation of mounting a connection structure 200 in an operation of forming a substrate portion 100 after an operation of forming a connection structure 200. The operation of forming the substrate 100 may be performed by a known build-up process, and thus, only the manufacturing method of the connection structure will be described below.

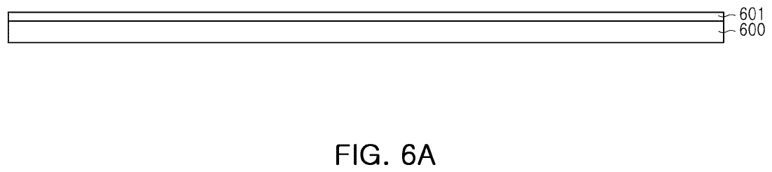

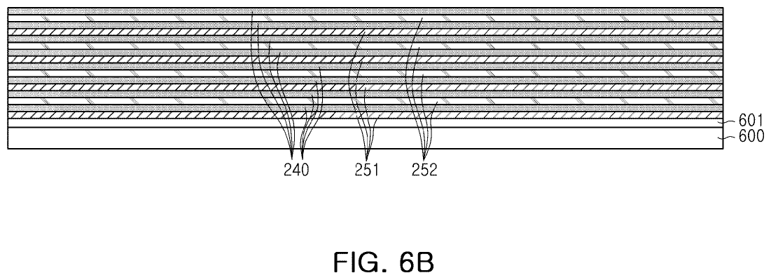

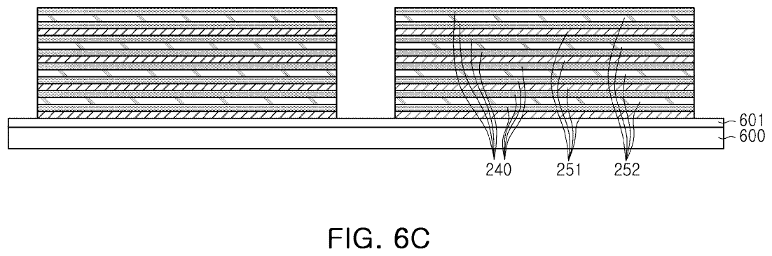

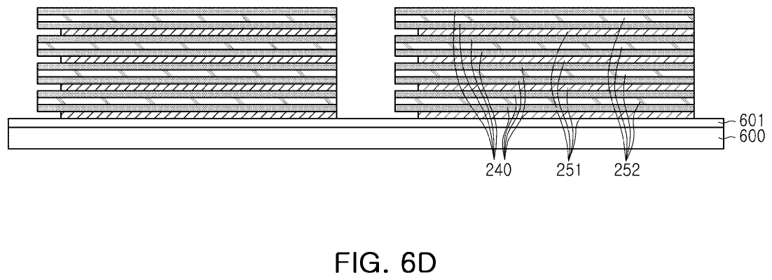

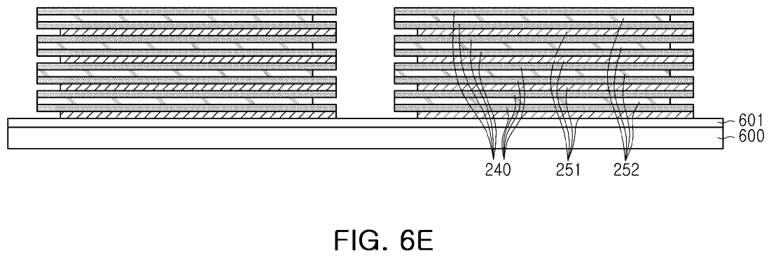

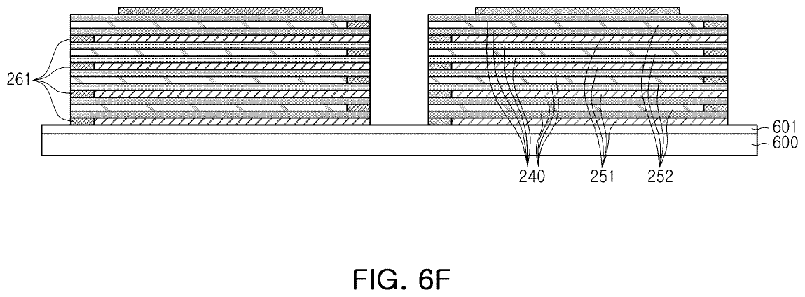

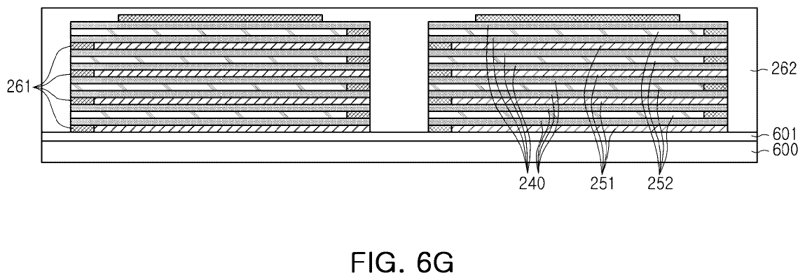

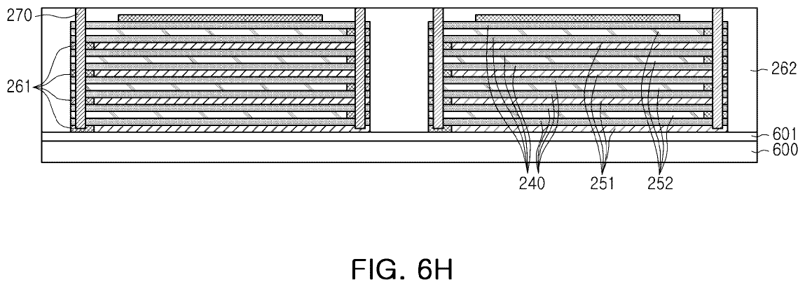

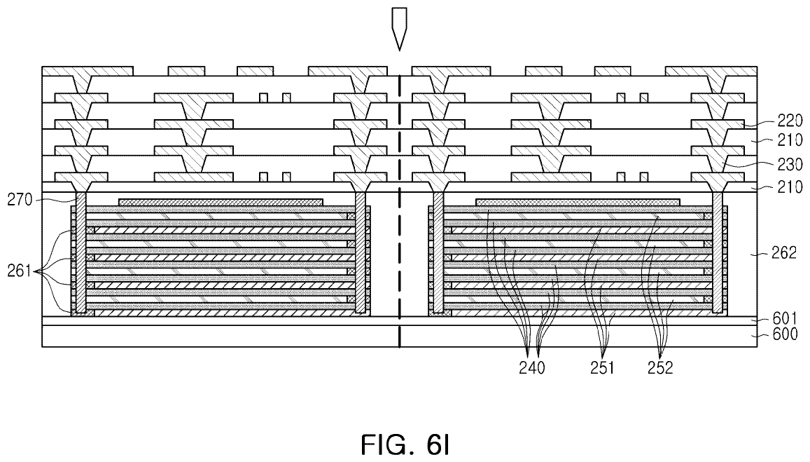

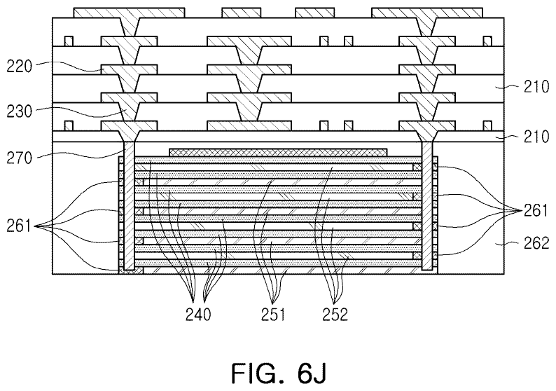

FIGS. 6A to 6J are cross-sectional views schematically illustrating a manufacturing method of the connection structure among the manufacturing methods of the printed circuit board according to an example.

Referring to FIGS. 6A to 6J, the manufacturing method of the connection structure of the printed circuit board according to an example is illustrated as forming a laminate of capacitor portions 202 in panel units on a support substrate 600, forming each wiring portion 201 on each unit laminate of the capacitor portion 202, and then completing a single connection structure. At this time, to express that a plurality of unit connection structures 200 may be manufactured, it is illustrated that two connection structures 200 may be formed in parallel, but the number of connection structures 200 that may be formed simultaneously is not necessarily limited thereto. Since the method of manufacturing the connection structure 200 of the printed circuit board according to an example includes an operation of singulating the connection structure 200 into a unit connection structure 200 after forming the connection structure 200 in multiples, the productivity may be increased.

Referring to FIG. 6A, the method of manufacturing the connection structure includes an operation of preparing a support substrate 600 on which a release layer 601 is formed. The support substrate 600 may be a silicon (Si) wafer substrate and may be a high-resolution de-bondable panel, but is not necessarily limited thereto. After completing the connection structure 200 by forming the capacitor portion 202 and the wiring portion 201, any substrate that may be separated from the connection structure 200 is sufficient. The release layer 601 may be formed by using a known material as a means for easily detaching the capacitor portion 202 and the support substrate 600 that are later placed on the lower side of the connection structure 200. The support substrate 600 may have a flat surface, which may be advantageous for laminating the dielectric layer 240, the first metal layer 251, and the second metal layer 252.

Referring to FIG. 6B, the method of manufacturing the connection structure may include an operation of forming the dielectric layer 240, the first metal layer 251, and the second metal layer 252 on the support substrate 600 and the release layer 601. At this time, the first metal layer 251, the dielectric layer 240, the second metal layer 252, and the dielectric layer 240 may be formed alternately in that order, and a laminate of the capacitor portion 202 may be formed. However, the stacking order is not limited to that illustrated in FIG. 6B, and the dielectric layer 240 may be stacked so that it is located at the lowest layer, and it is sufficient that the stacking is stacked so that the repeating unit of the stacking is constant. However, the present disclosure is not necessarily limited thereto, and the repeating unit of the laminate may be different depending on the capacitance of the capacitor portion 202 or the design of the connection structure 200. The laminate of the capacitor portion 202 may be formed in a panel unit on the support substrate 600, but it is not necessarily limited thereto, and may be formed only in a necessary area, and in this case, each laminate may be formed in a multiple form spaced apart from each other.

Referring to FIG. 6C, a unit laminate may be obtained by removing a portion of the laminate of the capacitor portion 202. The laminate of the capacitor portion 202 may be vertically cut to obtain a structure in which respective unit laminates are spaced apart from each other. At this time, the method of cutting the laminate may use dry etching, but is not limited thereto, and mechanical and chemical methods of removing a portion to cut the laminate into unit laminates may be used without limitation.

Referring to FIG. 6D, an operation of removing a portion of the first metal layer 251 from one side of the unit laminate of the capacitor portion 202 may be included. Since the first metal layer 251 and the second metal layer 252 include different metals, when an etching solution that reacts to the first metal layer 251 is used, the second metal layer 252 may not react. At this time, the operation of removing a portion of the first metal layer 251 may be performed only on one side of the unit laminate, and since a portion of the second metal layer 252 is to be removed on the other side opposite to the one side, the first metal layer 251 may be processed so that it does not react on the other side.

Referring to FIG. 6E, the operation of removing a portion of the second metal layer 252 on the other side of the unit laminate of the capacitor portion 202 may be included. Since the first metal layer 251 and the second metal layer 252 include different metals, if an etching solution that reacts to the second metal layer 252 is used, the first metal layer 251 may not react. At this time, the operation of removing a portion of the second metal layer 252 may be performed only on the other side of the unit laminate, and the second metal layer 252 may be processed so that it does not react on one side of the unit laminate.

Referring to FIGS. 6D and 6E, through the operation of removing a portion of each of the first metal layer 251 and the second metal layer 252, a groove may be formed in the first metal layer 251 and the second metal layer 252. Since the groove is later filled with a composition including an insulating material, the portion removed by the groove may be electrically insulated.

Referring to FIG. 6F, the operation of forming an insulating material 261 to fill the groove may be included. The method of forming the insulating material 261 may be performed by deposition or coating, and the insulating material 261 may also be disposed on the dielectric layer 240, and is not limited to that illustrated in FIG. 6C, and may also partially cover the side of the unit laminate of the capacitor portion 202. Meanwhile, the operation of filling the insulating material 261 may be omitted, and in this case, it may be replaced by the passivation layer 262 filling the groove in a later operation.

Referring to FIG. 6G, the operation of forming the passivation layer 262 to cover each unit laminate of the capacitor portion 202 may be included. The passivation layer 262 may be disposed to cover the unit laminate of the capacitor portion 202. At this time, the operation of flattening the upper surface of the passivation layer 262 may also be performed together.

Referring to FIG. 6H, an operation of forming a connecting metal 270 penetrating through at least a portion of the unit laminate of the capacitor portion 202, and the passivation layer 262, may be included. The operation of forming the connecting metal 270 may be performed by, but is not necessarily limited to, an operation of forming a through hole and an operation of plating to fill the through hole. By forming the connecting metal 270, one side of the unit laminate of the capacitor portion 202 may be connected to the second metal layer 252. Since a groove portion is formed at one side of the unit laminate of the capacitor portion 202 by removing a portion of the first metal layer 251 and the groove portion is filled with an insulating material, the first metal layer 251 and the connecting metal 270 may not be in contact with each other at one side, and the second metal layer 252 and the connecting metal 270 may be connected to each other. On the other side of the unit laminate of the capacitor portion 202, the connecting metal 270 and the first metal layer 251 may be connected.

Referring to FIG. 6I, an operation of forming a wiring portion 201 on a passivation layer 262 may be included. The method of forming the wiring portion 201 may be performed by a known build-up process. At this time, the connecting metal 270 may be electrically connected to the second wiring layer 220 through the second via layer 230 of the wiring portion 201.

Thereafter, referring to FIGS. 61 and 6J, the connection structure 200 may be cut along the cutting line to perform singulation, and the connection structure 200 may be completed by removing the release layer 601 and the support substrate 600.

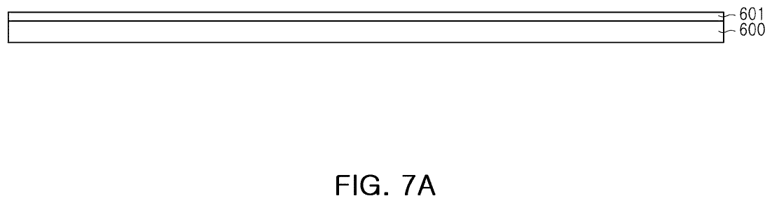

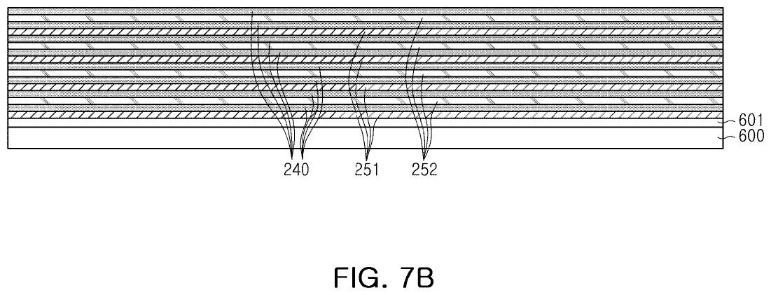

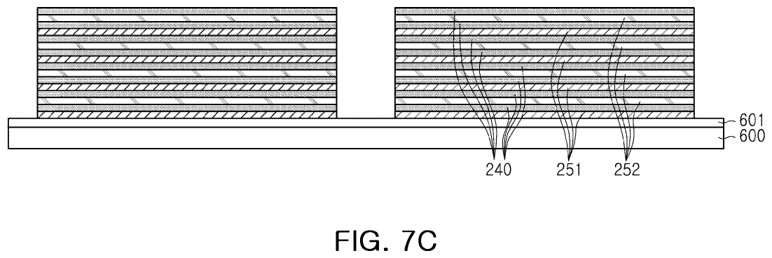

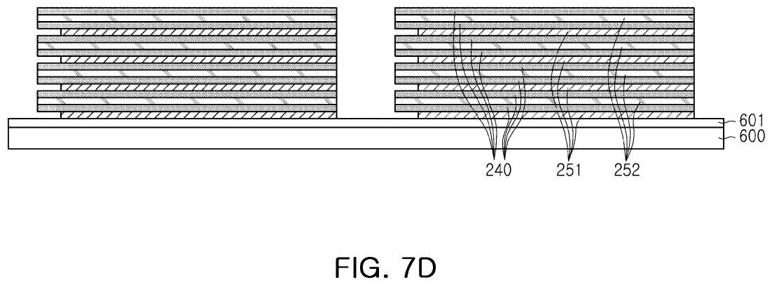

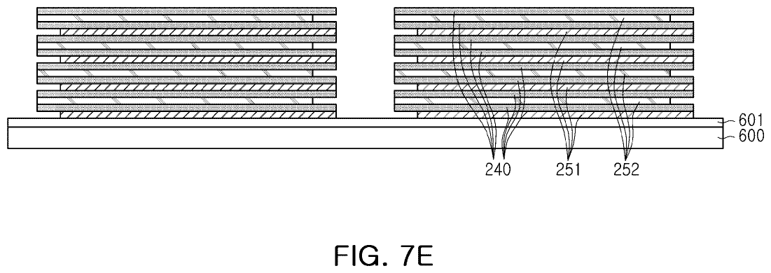

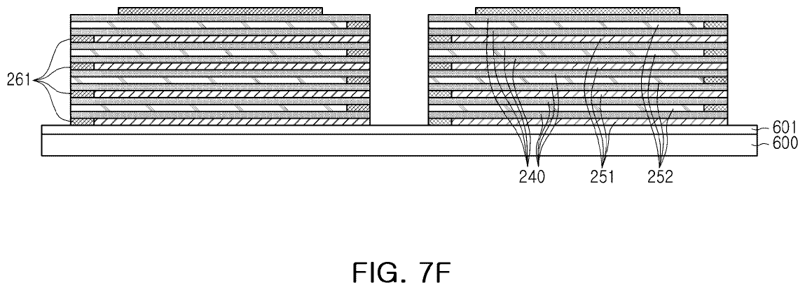

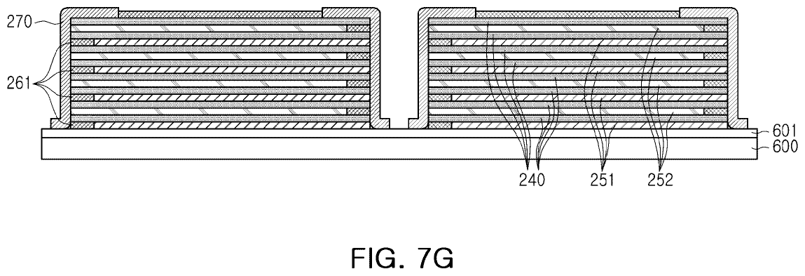

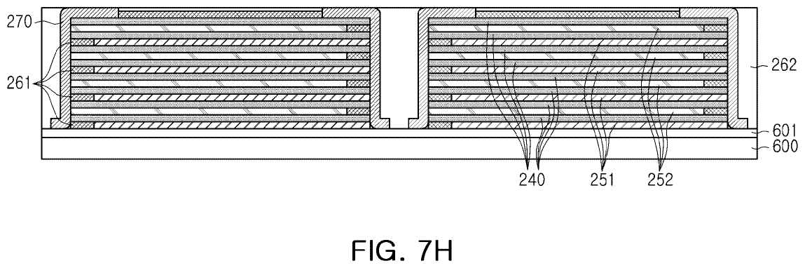

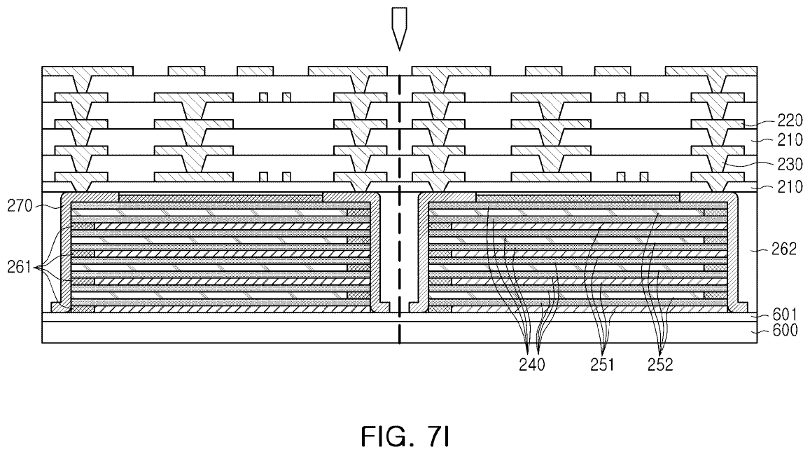

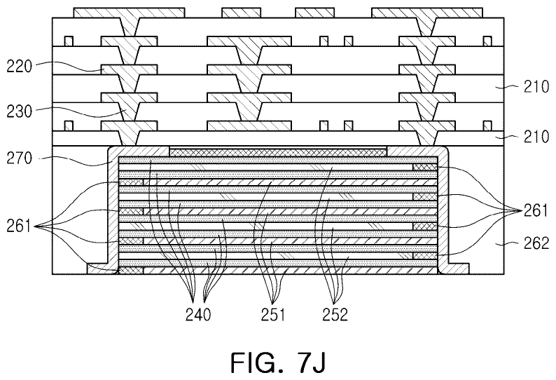

FIGS. 7A to 7J are cross-sectional views schematically illustrating a method of manufacturing a connection structure among methods of manufacturing a printed circuit board according to another example.

Referring to FIG. 7G, the operation of forming the connecting metal 270 may be performed before the operation of forming the passivation layer 262, and may be performed by forming the connecting metal 270 on each side of the unit laminate of the capacitor portion 202. The operation of forming the connecting metal 270 may be performed by plating, and may be patterned by performing electrolytic plating, but is not limited thereto, and may further include processes such as electroless plating or sputtering, if necessary.

The operations other than the description of FIG. 7G are the same as the manufacturing method of the connection structure of the printed circuit board according to an example, so that redundant description thereof is omitted.

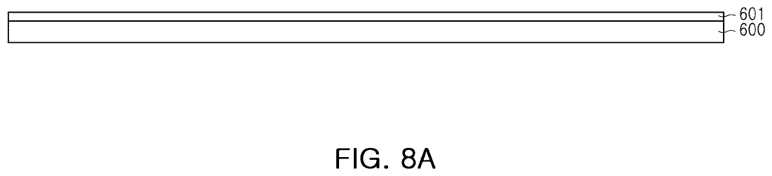

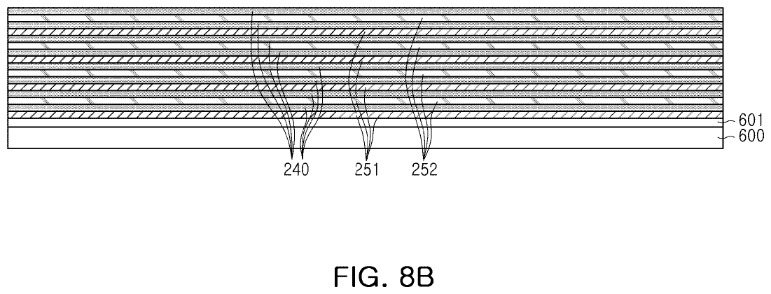

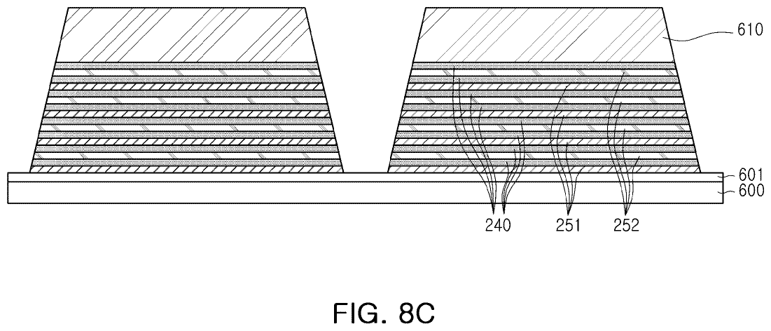

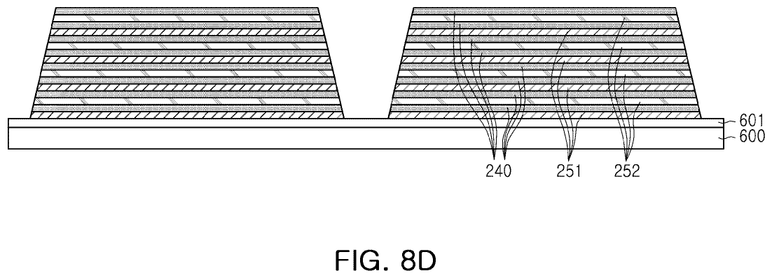

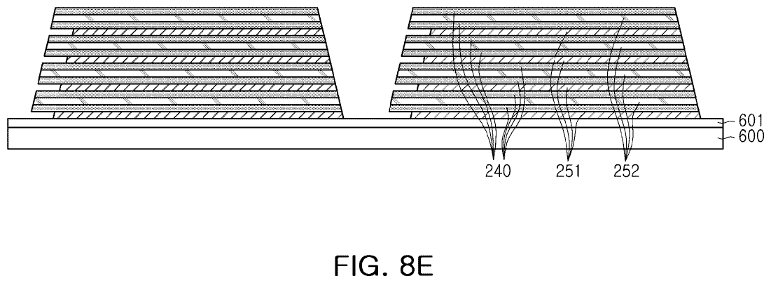

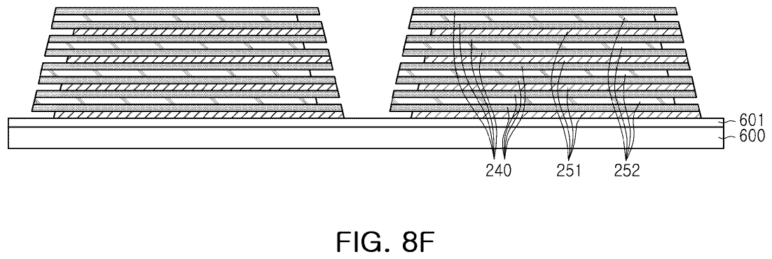

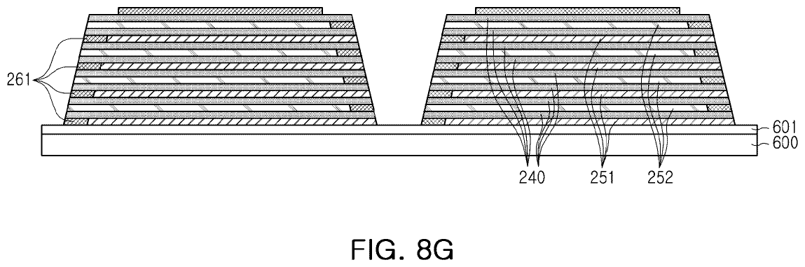

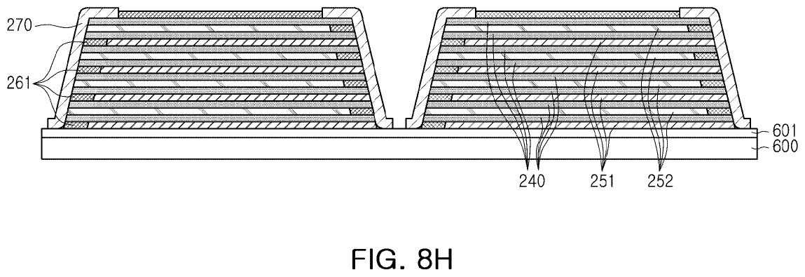

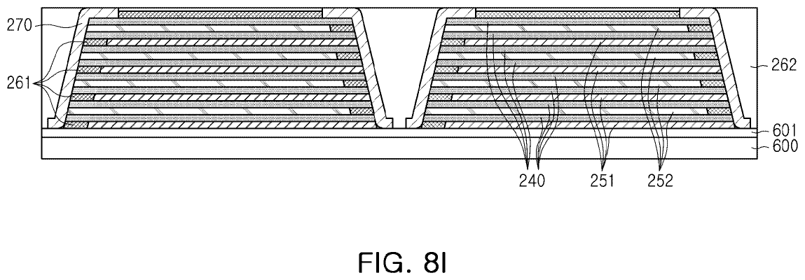

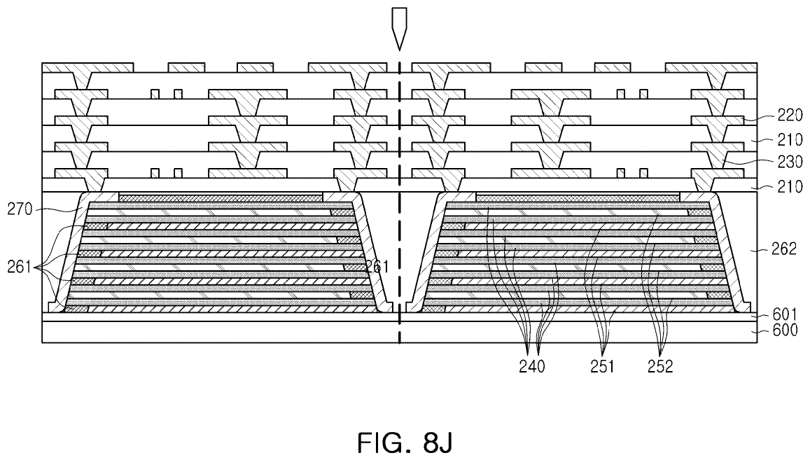

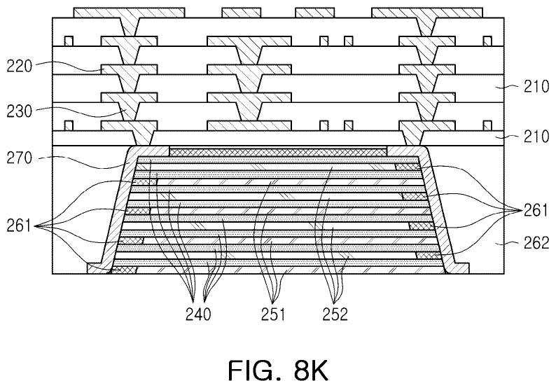

FIGS. 8A to 8K are cross-sectional views schematically illustrating the manufacturing method of the connection structure among the manufacturing methods of the printed circuit board according to another example.

Referring to FIG. 8C, the operation of cutting the laminate of the capacitor portion 202 into unit laminates may include an operation of forming an inclined surface. After forming a resist 610 having a trapezoidal shape on the laminate of the capacitor portion 202, an inclined surface may be formed on the side of the unit laminate through an etching process. At this time, a dry etching method may be used, but is not necessarily limited thereto, and any process that may form an inclined surface along the resist 610 may be used without limitation. The resist 610 may use a known etching resist. At this time, in FIG. 8C, the inclined surface of the resist 610 and the inclined surface of the laminate are depicted as being substantially the same, but the present disclosure is not limited thereto, and the inclined surface of the resist and the inclined surface of the laminate may be different from each other. Since the side of the laminate has an inclined surface, it may be easy for the solution to penetrate in the operation of removing a portion of the metal layer in the subsequent operation, and deposition, coating or plating may be easily performed in the operation of forming the insulating material 261 and the operation of forming the connecting metal 270.

Hereinafter, referring to FIG. 8D, an operation of removing the resist 610 may be included, and the operation of removing the resist 610 may use a known method of removing the resist without limitation.

Referring to FIG. 8H, the connecting metal 270 may be formed along the inclined surface of the unit laminate of the capacitor portion 202. The operation of forming the connecting metal 270 may be performed before the operation of forming the passivation layer 262, and may be performed by forming the connecting metal 270 on each side of the unit laminate of the capacitor portion 202. The operation of forming the connecting metal 270 may be performed by plating, and may be patterned by performing electrolytic plating, but is not limited thereto, and may further include processes such as electroless plating or sputtering, if necessary.

Operations other than those described for FIGS. 8C, 8D, and 8H are the same as those for the method of manufacturing a connection structure of a printed circuit board according to an example and the method of manufacturing a connection structure of a printed circuit board according to another example, so that redundant descriptions thereof are omitted.

As set forth above, a printed circuit board in which die-to-die interconnection may be performed on a printed circuit board for mounting electronic components, semiconductor chips, and the like may be provided.

A printed circuit board including a connection structure capable of implementing the function of a component in addition to the die-to-die interconnection may be provided.

A printed circuit board having improving reliability may be provided.

In this disclosure, the meaning of a cross-section may mean a cross-sectional shape when the object is cut vertically, or a cross-sectional shape when the object is viewed from the side. In addition, the meaning of “on a plane” may mean a shape when the object is cut horizontally, or a plane shape when the object is viewed from the top or bottom view.

In this disclosure, the terms such as upper side, upper portion, top, upper surface, and the like are used for convenience to mean a direction toward a surface on which electronic components may be mounted based on a cross-section of a drawing, and the terms such as lower side, lower portion, lower surface and the like are used in the opposite direction. However, this is defined for convenience of explanation, and it is obvious that the scope of the patent claims is not specifically limited by the description of such directions.

In this disclosure, the meaning of being connected includes not only being directly connected but also being indirectly connected through an adhesive layer or the like. In addition, the meaning of being electrically connected includes both cases where they are physically connected and cases where they are not connected.

In addition, the expressions first, second, and the like are used to distinguish one component from another component, and do not limit the order and/or importance of the components, and the like. In some cases, without exceeding the scope of the rights, the first component may be referred to as the second component, and similarly, the second component may be referred to as the first component.

The expression “an example” used in this disclosure does not mean an identical embodiment, but is provided to emphasize and explain each unique feature. However, the examples presented above do not exclude implementations in combination with features of other examples. For example, even if a matter described in a specific example is not described in another example, it may be understood as a description related to the other example, unless there is a description that is contrary or contradictory to that matter in the other example.

The terms used in this disclosure are used for describing examples only and are not intended to limit this disclosure. In this case, singular expressions include plural expressions unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a substrate portion including a first insulating layer, first wiring layers disposed on or within the first insulating layer, and a first via layer penetrating through at least a portion of the first insulating layer to connect the first wiring layers to each other; and
a connection structure disposed within the substrate portion and including a capacitor portion, a passivation layer covering the capacitor portion, and a wiring portion disposed on the passivation layer,
wherein the capacitor portion of the connection structure includes a plurality of dielectric layers, a first metal layer and a second metal layer alternately disposed with the plurality of dielectric layers interposed therebetween, a first insulating material disposed on the same level as the first metal layer, on one side of the capacitor portion, a second insulating material disposed on the same level as the second metal layer, on the other side opposite to the one side of the capacitor portion, a first connecting metal connected to the first metal layer, and a second connecting metal connected to the second metal layer.

2. The printed circuit board of claim 1, wherein the wiring portion of the connection structure includes a second insulating layer, second wiring layers disposed on the second insulating layer, a second via layer penetrating through at least a portion of the second insulating layer to connect the second wiring layers to each other, and a third via layer connecting one of the second wiring layers and the first connecting metal to each other and connecting the one of the second wiring layers and the second connecting metal to each other.

3. The printed circuit board of claim 2, wherein a wiring density of the second wiring layers is greater than a wiring density of the first wiring layers.

4. The printed circuit board of claim 1, wherein the first connecting metal penetrates the plurality of dielectric layers, the first metal layer, and the second insulating material, and
the second connecting metal penetrates the plurality of dielectric layers, the second metal layer, and the first insulating material.

5. The printed circuit board of claim 1, wherein the first connecting metal is disposed on the other side of the capacitor portion and connected to the first metal layer, and
the second connecting metal is disposed on the one side of the capacitor portion and connected to the second metal layer.

6. The printed circuit board of claim 1, wherein the capacitor portion has the one side and the other side with an inclined surface.

7. The printed circuit board of claim 1, wherein the capacitor portion has a trapezoidal shape such that a width at an upper side is narrower than a width at a lower side.

8. The printed circuit board of claim 1, wherein the first insulating material and the second insulating material are respectively disposed between the plurality of dielectric layers.

9. The printed circuit board of claim 8, wherein a thickness of the first insulating material is substantially the same as a thickness of the first metal layer.

10. The printed circuit board of claim 1, further comprising an adhesive layer interposed between the connection structure and the substrate portion.

11. The printed circuit board of claim 1, wherein the first insulating material extends to the second insulating material, and the first insulating material and the second insulating material form a single body.

12. The printed circuit board of claim 1, wherein the first insulating material or the second insulating material is also disposed on an uppermost one of the plurality of dielectric layers.

13. A printed circuit board comprising:
a substrate portion including a first insulating layer, and a first wiring layer disposed on or within the first insulating layer; and
a connection structure disposed within the substrate portion and including a capacitor portion, a passivation layer covering the capacitor portion, and a wiring portion disposed on the passivation layer,
wherein the capacitor portion includes a plurality of dielectric layers, a first metal layer and a second metal layer alternately disposed with the plurality of dielectric layers interposed therebetween, a first connecting metal connected to the first metal layer, and a second connecting metal connected to the second metal layer, and
the first metal layer includes a metal different from a metal of the second metal layer.

14. The printed circuit board of claim 13, wherein the first metal layer includes molybdenum (Mo).

15. The printed circuit board of claim 14, wherein the second metal layer comprises titanium (Ti).

16. The printed circuit board of claim 13, wherein the first connecting metal and the second connecting metal each comprise a metal different from the first metal layer, and
the first connecting metal and the second connecting metal each include a metal different from the second metal layer.

17. The printed circuit board of claim 16, wherein the first connecting metal and the second connecting metal each comprise copper (Cu).

18. The printed circuit board of claim 13, wherein each of the plurality of dielectric layers includes an oxide and/or a nitride.

19. The printed circuit board of claim 18, wherein each of the plurality of dielectric layers comprises at least one material among SiO₂, Si₃N₄, Al₂O₃, AlN, MgO, Y₂O₃, HfO₂, ZrO₂, and Ta₂O₃.

20. The printed circuit board of claim 13, wherein the first metal layer is spaced apart from one edge of the capacitor portion, and the second metal layer is spaced apart from another edge of the capacitor portion opposing the one edge.
